(19) United States
(12) Patent Application Publication
(10) Pub. No.: US 2025/0113438 A1
(43) Pub. Date: Apr. 3, 2025

(54) WIRING BOARD AND SEMICONDUCTOR DEVICE

(71) Applicant: SHINKO ELECTRIC INDUSTRIES CO., LTD., Nagano (JP)

(72) Inventors: Tomoyuki SHIMODAIRA, Nagano (JP); Kiyoshi OI, Nagano (JP); Hitoshi KONDO, Nagano (JP)

(21) Appl. No.: 18/884,616

(22) Filed: Sep. 13, 2024

(30) Foreign Application Priority Data
Sep. 28, 2023 (JP) 2023-167515

(51) Int. Cl. H05K 1/18; H01L 21/48; H01L 23/498; H01L 23/538; H01L 23/64; H05K 1/11; H05K 3/42

(52) U.S. Cl. CPC H05K 1/187; H01L 21/4857; H01L 21/486; H01L 23/49822; H01L 23/49838; H01L 23/5383; H01L 23/5386; H01L 23/5389; H05K 1/113; H05K 1/181; H05K 3/429; H01L 23/49866; H01L 23/642; H05K 2201/0776; H05K 2201/09481; H05K 2201/09509; H05K 2201/09618; H05K 2201/09827; H05K 2201/10522; H05K 2201/10537

(57) ABSTRACT

A wiring board includes a first interconnect structure including a first interconnect layer and a first insulating layer, a second interconnect structure, including a second interconnect layer and a second insulating layer, and laminated on one side of the first interconnect structure, and a third interconnect structure, including a third interconnect layer and a third insulating layer, and laminated on the other side of the first interconnect structure. The second interconnect layer has an interconnect density higher than those of the first and the third interconnect layers. The first insulating layer has a through hole penetrating the first insulating layer, and an electronic component electrically connected to the second interconnect layer is disposed inside the through hole. An embedding resin covering the electronic component is provided inside the through hole, and extends to cover the first insulating layer and fills in between the first and second insulating layers.

### CROSS-REFERENCE TO RELATED APPLICATIONS

This application is based upon and claims priority to Japanese Patent Application No. 2023-167515, filed on Sep. 28, 2023, the entire contents of which are incorporated herein by reference.

### FIELD

Certain aspects of the embodiments discussed herein are related to wiring boards, semiconductor devices, and methods for manufacturing wiring boards.

### BACKGROUND

In a case where a semiconductor chip is provided on a wiring board, the semiconductor chip is mounted via an interconnect structure serving as an interposer having micro-interconnects, for example. The interposer includes a silicon substrate, a glass substrate, an organic substrate, or the like. A technique of embedding a capacitor in such a wiring board has been proposed (refer to International Publication Pamphlet No. WO 2021/084750, for example). In such a wiring board, a resistance loss is preferably as small as possible.

### SUMMARY

Accordingly, it is an object in one aspect of the embodiments to provide a technique for reducing a resistance loss in a wiring board having an electronic component embedded therein.

According to one aspect of the embodiments, a wiring board includes a first interconnect structure including a first interconnect layer and a first insulating layer; a second interconnect structure, including a second interconnect layer and a second insulating layer, and laminated on one side of the first interconnect structure; and a third interconnect structure, including a third interconnect layer and a third insulating layer, and laminated on the other side of the first interconnect structure, wherein the second interconnect layer has an interconnect density higher than interconnect densities of the first interconnect layer and the third interconnect layer, the first insulating layer has a through hole penetrating the first insulating layer, an electronic component electrically connected to the second interconnect layer is disposed inside the through hole, an embedding resin covering the electronic component is provided inside the through hole, and the embedding resin extends from inside the through hole to cover the first insulating layer, and fills in between the first insulating layer and the second insulating layer.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view illustrating an example of a wiring board according to a first embodiment;

FIG. 2A, FIG. 2B, FIG. 2C, FIG. 2D, and FIG. 2E are diagrams (part 1) illustrating examples of manufacturing processes of the wiring board according to the first embodiment;

FIG. 3A, FIG. 3B, FIG. 3C, and FIG. 3D are diagrams (part 2) illustrating examples of the manufacturing processes of the wiring board according to the first embodiment;

FIG. 4A, FIG. 4B, and FIG. 4C are diagrams (part 3) illustrating examples of the manufacturing processes of the wiring board according to the first embodiment;

FIG. 5 is a cross sectional view illustrating an example of the wiring board according to a first modification of the first embodiment;

FIG. 6A, FIG. 6B, FIG. 6C, and FIG. 6D are diagrams illustrating examples of manufacturing processes of the wiring board according to the first modification of the first embodiment;

FIG. 7 is a cross sectional view illustrating an example of the wiring board according to a second modification of the first embodiment;

FIG. 8 is a cross sectional view illustrating an example of the wiring board according to a third modification of the first embodiment;

FIG. 9A, FIG. 9B, and FIG. 9C are diagrams illustrating examples of the manufacturing processes of the wiring board according to the third modification of the first embodiment;

FIG. 10 is a cross sectional view illustrating an example of the wiring board according to a fourth modification of the first embodiment;

FIG. 11 is a cross sectional view illustrating an example of the wiring board according to a fifth modification of the first embodiment;

FIG. 12A, FIG. 12B, and FIG. 12C are diagrams illustrating examples of the manufacturing processes of the wiring board according to the fifth modification of the first embodiment; and

FIG. 13 is a cross sectional view illustrating an example of a semiconductor device according to an application example of the first embodiment.

### DESCRIPTION OF EMBODIMENTS

Hereinafter, embodiments of the present disclosure will be described with reference to the drawings. In the drawings, the same constituent elements or components are designated by the same reference numerals, and a redundant description thereof may be omitted.

### First Embodiment

### Configuration of Wiring Board

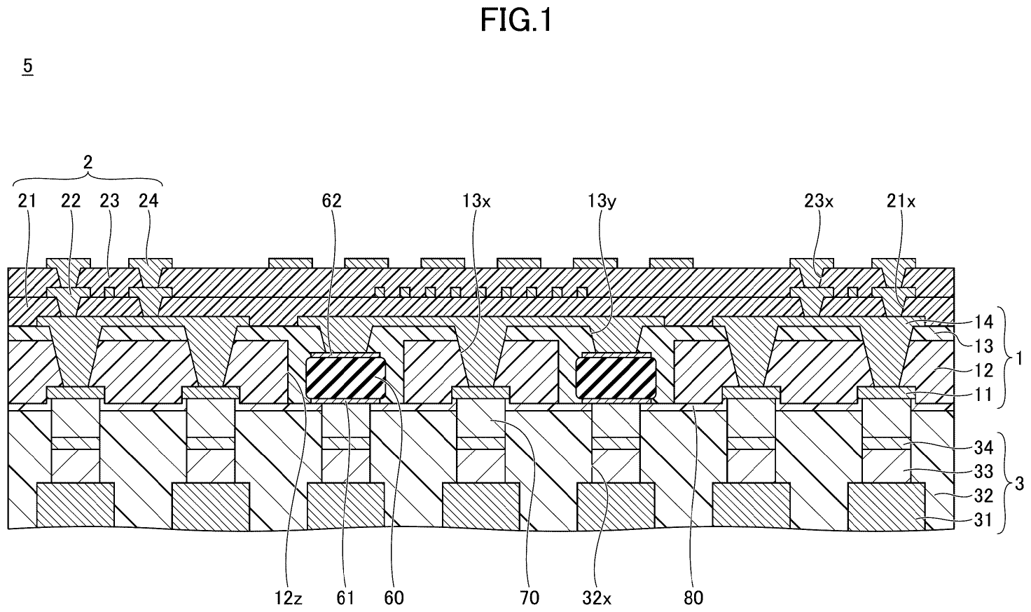

FIG. 1 is a cross sectional view illustrating an example of a wiring board according to a first embodiment. As illustrated in FIG. 1, a wiring board 5 includes a first interconnect structure 1, a second interconnect structure 2, and a third interconnect structure 3. The second interconnect structure 2 is laminated on one side of the first interconnect structure 1 in a thickness direction of the first interconnect structure. The third interconnect structure 3 is laminated on the other side of the first interconnect structure 1 in the thickness direction of the first interconnect structure. That is, the third interconnect structure 3 is arranged on an opposite side from the second interconnect structure 2 with the first interconnect structure 1 interposed therebetween.

In the present embodiment, for sake of convenience, the side of the wiring board 5 provided with an insulating layer 23 in FIG. 1 may be referred to as an upper side or one side, and the side of the wiring board 5 provided with an insulating layer 32 may be referred to as a lower side or the other side. The insulating layer 23 and the insulating layer 32 will be described later. In addition, a surface of each portion on the side of the wiring board 5 provided with the insulating layer 23 may be referred to as one surface or an upper surface, and a surface of each portion on the side of the wiring board 5 provided with the insulating layer 32 may be referred to as the other surface or a lower surface. However, the wiring board 5 can be used in an upside-down state or can be disposed at an arbitrary angle. Moreover, a plan view refers to a view of an object, viewed from above, in a normal direction with respect to an upper surface of the insulating layer 23. A planar shape refers to a shape of an object in the plan view, viewed from above, in the normal direction with respect to the upper surface of the insulating layer 23.

The first interconnect structure 1 has a configuration including an interconnect layer and an insulating layer are laminated. The interconnect layer of the first interconnect structure 1 may be referred to as a first interconnect layer, the insulating layer of the first interconnect structure 1 may be referred to as a first insulating layer, and a via interconnect of the first interconnect structure 1 may be referred to as a first via interconnect. In the example illustrated in FIG. 1, the first interconnect structure 1 includes an interconnect layer 11 and an interconnect layer 14 as the first interconnect layer, and an insulating layer 12 as the first insulating layer. In the first interconnect structure 1, the number of first interconnect layers and the number of first insulating layers are not limited to those of the example illustrated in FIG. 1.

In the first interconnect structure 1, the interconnect layer 11 is embedded in a lower surface of the insulating layer 12. A lower surface of the interconnect layer 11 is exposed from the lower surface of the insulating layer 12, and an upper surface and a side surface of the interconnect layer 11 are covered with the insulating layer 12. In the example illustrated in FIG. 1, the lower surface of the interconnect layer 11 is recessed more toward the interconnect layer 14 than the lower surface of the insulating layer 12 is toward the interconnect layer 14. However, the lower surface of the interconnect layer 11 may coincide with the lower surface of the insulating layer 12.

The lower surface of the interconnect layer 11, exposed from the lower surface of the insulating layer 12, is formed to have a circular planar shape, for example, and can be used as a pad to be connected to the third interconnect structure 3. The interconnect layer 11 may include an interconnect pattern in addition to the pad. A material used for the interconnect layer 11 may be copper (Cu) or the like, for example. The interconnect layer 11 may have a laminated structure (or multi-layer structure) having a plurality of metal layers. A thickness of the interconnect layer 11 may be in a range of approximately 10 μm to approximately 35 μm, for example. A line-and-space (hereinafter simply referred to as “line/space”) of the interconnect layer 11 may be in a range of approximately 10 μm/10 μm to approximately 50 μm/50 μm, for example.

In the line/space, the line represents an interconnect width, and the space represents an interval between adjacent interconnects (interconnect spacing). In a case where the line/space is described as being in the range of 10 μm/10 μm to 50 μm/50 μm, it is indicated that the interconnect width is 10 μm or more and 50 μm or less and the interconnect interval between the adjacent interconnects is 10 μm or more and 50 μm or less. The interconnect width and the interconnect interval do not necessarily have to be the same.

The insulating layer 12 is formed so as to cover the upper surface and the side surface of the interconnect layer 11. A material used for the insulating layer 12 includes a non-photosensitive resin as a main component thereof, for example. The main component of the material used for the insulating layer 12 may include a thermosetting non-photosensitive resin, such as an epoxy-based resin, an imide-based resin, a phenol-based resin, a cyanate-based resin, or the like, for example. A thickness of the insulating layer 12 may be in a range of approximately 20 μm to approximately 150 μm, for example. The insulating layer 12 may include a filler, such as silica (SiO₂) or the like.

The insulating layer 12 has a through hole 12z that penetrates the insulating layer 12. An electronic component 60 is disposed inside the through hole 12z. The electronic component 60 may be a passive component or an active component. Both the passive component and the active component may coexist in the electronic component 60. The electronic component 60 is an intelligent power device (IPD), a semiconductor chip, a capacitor, an inductor, a resistor, or the like, for example. A planar shape of the through hole 12z is similar to the planar shape of the electronic component 60, for example, and a size of through hole 12z is larger than a size of the electronic component 60. The electronic component 60 has an electrode 61 on a lower portion thereof, and an electrode 62 on an upper portion thereof.

An embedding resin 13 is provided inside the through hole 12z and covers the electronic component 60, extends upward from inside the through hole 12z and covers an upper surface of the insulating layer 12, and is filled between the insulating layer 12 as the first insulating layer and the insulating layer 21 as the second insulating layer. A lower surface of the electrode 61 of the electronic component 60 is exposed from the embedding resin 13. The lower surface of the electrode 61 of the electronic component 60 may coincide with a lower surface of the embedding resin 13, for example. In addition, the lower surface of the embedding resin 13 may coincide with the lower surface of the insulating layer 12. A material used for the embedding resin 13 may be the same as the material used for the insulating layer 12, for example. The material used for the embedding resin 13 may be different from the material used for the insulating layer 12. A thickness of a portion of the embedding resin 13 laminated on the upper surface of the insulating layer 12 may be in a range of approximately 20 μm to approximately 50 μm, for example. The embedding resin 13 may include a filler, such as silica (SiO₂) or the like.

The insulating layer 12 and the embedding resin 13 are interlayer insulating layers located between the interconnect layer 11 and the interconnect layer 14. The insulating layer 12 and the embedding resin 13 have a via hole 13x that penetrates the insulating layer 12 and the embedding resin 13 and exposes an upper surface of the interconnect layer 11. Further, the embedding resin 13 has a via hole 13y that penetrates the embedding resin 13 and exposes an upper surface of the electrode 62 of the electronic component 60. The via hole 13x may have an inverted truncated cone shape such that a diameter of the via hole 13x that opens toward the second interconnect structure 2 is larger than a diameter of a bottom surface of the via hole 13x formed by the upper surface of the interconnect layer 11. The via hole 13y may have an inverted truncated cone shape such that a diameter of the via hole 13y that opens toward the second interconnect structure 2 is larger than a diameter of a bottom surface of the via hole 13y formed by the upper surface of the electrode 62.

The interconnect layer 14 is formed on upper portions of the insulating layer 12 and the embedding resin 13, and inside the insulating layer 12 and the embedding resin 13. The interconnect layer 14 includes via interconnects formed inside the via hole 13x and the via hole 13y, and an interconnect pattern formed on an upper surface of the embedding resin 13. The interconnect pattern includes a portion electrically connected to the interconnect layer 11 through the via interconnect filling the via hole 13x. Moreover, the interconnect pattern includes a portion electrically connected to the electrode 62 of the electronic component 60 through the via interconnect filling the via hole 13y. A material used for the interconnect layer 14 and a thickness of the interconnect pattern may be the same as those of the interconnect layer 11, for example. In addition, a line/space of the interconnect pattern of the interconnect layer 14 may be the same as that of the interconnect layer 11, for example.

The second interconnect structure 2 has a configuration including an interconnect layer and an insulating layer that are laminated. The interconnect layer of the second interconnect structure 2 may be referred to as a second interconnect layer, the insulating layer of the second interconnect structure 2 may be referred to as a second insulating layer, and a via interconnect of the second interconnect structure 2 may be referred to as a second via interconnect. In the example illustrated in FIG. 1, the second interconnect structure 2 includes interconnect layers 22 and 24 as the second interconnect layer, and insulating layers 21 and 23 as the second insulating layer. In the second interconnect structure 2, the number of second interconnect layers and the number of second insulating layers are not limited to those of the example illustrated in FIG. 1.

An interconnect width and an interconnect interval of the second interconnect layer configuring the second interconnect structure 2 are smaller than the interconnect width and the interconnect interval of the first interconnect layer configuring the first interconnect structure 1, respectively. That is, the second interconnect layer is a fine interconnect layer having an interconnect density higher than an interconnect density of the first interconnect layer.

The insulating layer 21 is provided on the upper surface of the embedding resin 13, and covers an upper surface and a side surface of an interconnect pattern forming the interconnect layer 14. A material used for the insulating layer 21 includes a non-photosensitive resin as a main component thereof, for example. The main component of the material used for the insulating layer 21 may include a thermosetting non-photosensitive resin, such as an epoxy-based resin, an imide-based resin, a phenol-based resin, or a cyanate-based resin, or the like, for example. The insulating layer 21 may include a filler, such as silica (SiO₂) or the like. A thickness of the insulating layer 21 is smaller than a total thickness of the insulating layer 12 and the embedding resin 13. The thickness of the insulating layer 21 may be in a range of approximately 3 μm to approximately 20 μm, for example. The insulating layer 21 has a via hole 21x that penetrates the insulating layer 21 and reaches an upper surface of the interconnect layer 14.

The interconnect layer 22 is formed on one side of the insulating layer 21, and is electrically connected to the interconnect layer 14 of the first interconnect structure 1. The interconnect layer 22 fills the via hole 21x, and extends to an upper surface of the insulating layer 21. A portion of the interconnect layer 22 filling the via hole 21x forms a via interconnect, and a portion of the interconnect layer 22 extending to the upper surface of the insulating layer 21 forms an interconnect pattern. A material mainly used for the interconnect layer 22 may be copper (Cu) or the like, for example. A thickness of the interconnect pattern forming the interconnect layer 22 may be in a range of approximately 1 μm to approximately 10 μm, for example. A line/space of the interconnect pattern forming the interconnect layer 22 may be in a range of approximately 1 μm/1 μm to approximately 8 μm/8 μm, for example.

The insulating layer 23 is provided on one surface of the insulating layer 21, and covers an upper surface and a side surface of the interconnect layer 22. A material used for the insulating layer 23 and a thickness of the insulating layer 23 may be the same as those of the insulating layer 21, for example. The insulating layer 23 may include a filler, such as silica (SiO₂) or the like. The insulating layer 23 has a via hole 23x that penetrates the insulating layer 23 and reaches the upper surface of the interconnect layer 22.

The interconnect layer 24 is formed on one side of the insulating layer 23, and is electrically connected to the interconnect layer 22. The interconnect layer 24 fills the via hole 23x, and extends to an upper surface of the insulating layer 23. A portion of the interconnect layer 24 filling the via hole 23x forms a via interconnect, and a portions of the interconnect layer 24 extending to the upper surface of the insulating layer 23 forms an interconnect pattern and an electrode. A material used for the interconnect layer 24, a thickness of the interconnect pattern of the interconnect layer 24, and a line/space of the interconnect pattern of the interconnect layer 24 may be the same as those of the interconnect layer 22, for example. The electrode forming the interconnect layer 24 can be used for making an electrical connection with an electronic component, such as a semiconductor chip or the like. The interconnect layer 24 is electrically connected to the electronic component 60 via the interconnect layer 22 and the interconnect layer 14.

The third interconnect structure 3 has a configuration including an interconnect layer and an insulating layer that are laminated. The interconnect layer of the third interconnect structure 3 may be referred to as a third interconnect layer, and the insulating layer of the third interconnect structure 3 may be referred to as a third insulating layer. In the example illustrated in FIG. 1, the third interconnect structure 3 includes an interconnect layer 31 as the third interconnect layer, and an insulating layer 32 as the third insulating layer. In the third interconnect structure 3, the number of third interconnect layers and the number of third insulating layers is not limited to those of the example illustrated in FIG. 1.

An interconnect width and an interconnect interval of the second interconnect layer forming the second interconnect structure 2 are smaller than the interconnect width and the interconnect interval of the third interconnect layer forming the third interconnect structure 3, respectively. That is, the second interconnect layer is a fine interconnect layer having an interconnect density higher than an interconnect density of the third interconnect layer.

The third interconnect structure 3 may include a pad or the like connected to the first interconnect structure 1, and may be a known build-up wiring board, for example. For this reason, only a portion of the third interconnect structure 3 near the first interconnect structure 1 is illustrated in FIG. 1, and an illustration of the lower insulating layer and interconnect layer is omitted.

The interconnect layer 31 is an uppermost interconnect layer of the third interconnect structure 3. The interconnect layer 31 includes at least a pad. The interconnect layer 31 may include an interconnect pattern in addition to the pad. The pad forming the interconnect layer 31 may have a circular planar shape, for example. A material used for the interconnect layer 31 may be copper (Cu) or the like, for example.

The insulating layer 32 is an uppermost insulating layer of the third interconnect structure 3, and is a so-called solder resist layer or a build-up resin layer. In a case where the insulating layer 32 is the solder resist layer, the material used for the insulating layer 32 may be a photosensitive insulating resin including a phenol-based resin, a polyimide-based resin, or the like as a main component thereof. In a case where the insulating layer 32 is the build-up resin layer, the material used for the insulating layer 32 may be the same as that of the insulating layer 12 of the first interconnect structure 1, for example. The insulating layer 32 may include a filler, such as silica (SiO₂) or the like. The insulating layer 32 has an opening 32x, and an upper surface of the pad forming the interconnect layer 31 is exposed inside the opening 32x.

Metal layers 33 and 34 are provided, as required. The metal layer 33 is laminated on an upper surface of the interconnect layer 31 exposed inside the opening 32x. The metal layer 34 is laminated on an upper surface of the metal layer 33 exposed inside the opening 32x. An example of the metal layer 33 includes a Ni layer, for example. Examples of the metal layer 34 include an Au layer, a Pd/Au layer (a metal laminate layer in which a Pd layer and an Au layer are laminated in this order), or the like, for example.

The metal layer 34 of the third interconnect structure 3 and the interconnect layer 11 of the first interconnect structure 1 are electrically connected via a bonding member 70. For example, solder may be used as the bonding member 70. Examples of the material used for the solder include an alloy including Pb, an alloy of Sn and Cu, an alloy of Sn and Ag, an alloy of Sn, Ag, and Cu, or the like, for example. An underfill resin 80 may be provided between an upper surface of the insulating layer 32 of the third interconnect structure 3 and the lower surfaces of the insulating layer 12 and the embedding resin 13 of the first interconnect structure 1.

Accordingly, the wiring board 5 has the electronic component 60 embedded in the first interconnect structure 1. Because the second interconnect structure 2 having the fine interconnect has a small thickness as a whole, it is difficult to embed the electronic component 60 in the second interconnect structure 2. In contrast, the first interconnect structure 1 has a larger thickness as a whole compared to the second interconnect structure 2, and thus, the electronic component 60 can be embedded in the first interconnect structure 1.

The electronic component 60 is electrically connected to a semiconductor chip or the like provided on the second interconnect structure 2. In this case, because the thickness of the second interconnect structure 2 as a whole is small, a distance between the electronic component 60 and the semiconductor chip or the like in the thickness direction can be reduced. Hence, an electrical path between the electronic component 60 and the semiconductor chip or the like can be reduced, thereby reducing a resistance loss. As a result, it is possible to improve a power supply efficiency and stabilize power supply.

In addition, a large number of electronic components 60 can be embedded in the wiring board 5 without enlarging the planar shape of the wiring board 5. If there is a margin in space, other electronic components can also be provided on an upper surface of the wiring board 5.

### Method for Manufacturing Wiring Board

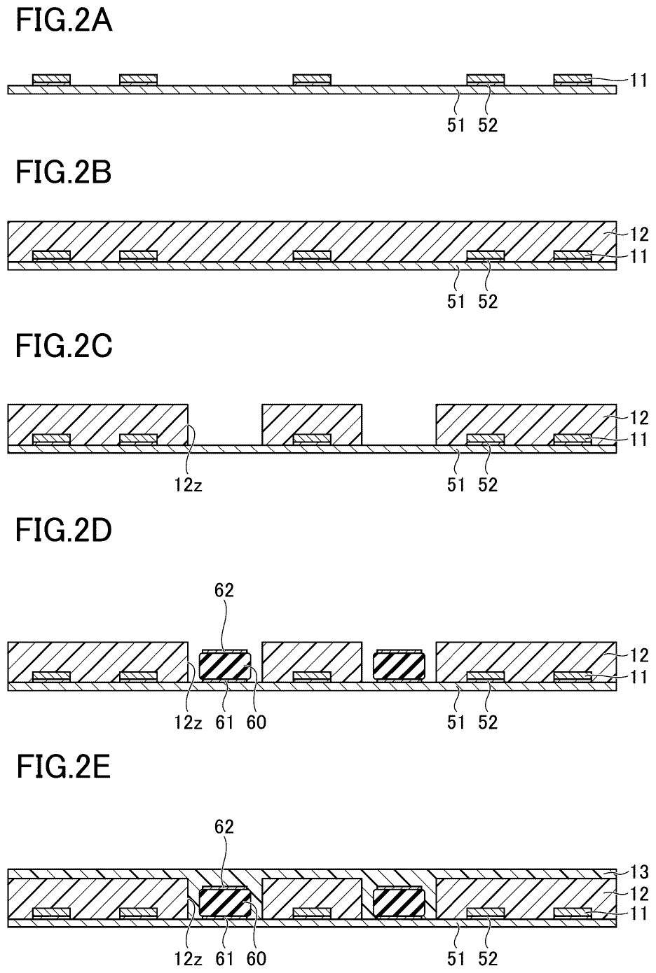

Next, a method for manufacturing the wiring board according to the first embodiment will be described. FIG. 2A through FIG. 4C are diagrams illustrating manufacturing processes of the wiring board according to the first embodiment. Although an example of the manufacturing processes for manufacturing one wiring board is illustrated, the wiring board may be manufactured by manufacturing a plurality of portions that become the wiring board, and segmenting the plurality of portions into individual wiring boards.

First, in the process (or step) illustrated in FIG. 2A, patterned sacrificial layer 52 and interconnect layer 11 are formed on a support 51. For example, a copper foil having a thickness in a range of approximately 20 μm to approximately 70 μm can be used as the support 51. When forming the sacrificial layer 52 and the interconnect layer 11, a dry film resist is disposed on an upper surface of the support 51, and the dry film resist is exposed and developed to form a resist layer having openings in portions where the sacrificial layer 52 and the interconnect layer 11 are to be formed, for example. Next, the sacrificial layer 52 and the interconnect layer 11 are successively formed on the upper surface of the support 51 exposed inside the openings of the resist layer by electrolytic plating using power supplied from the support 51. The sacrificial layer 52 is a layer to be finally removed, and is formed of a material different from the material used for the interconnect layer 11. The sacrificial layer 52 may be formed of nickel (Ni), for example. The interconnect layer 11 may be formed of copper (Cu), for example. Thereafter, the resist layer is removed. The resist layer can be removed using a resist stripper (or resist removing solution), for example.

Next, in the process (or step) illustrated in FIG. 2B, the insulating layer 12 is formed on the upper surface of the support 51 to cover the sacrificial layer 52 and the interconnect layer 11. Specifically, a semi-cured insulating resin film including a thermosetting resin as a main component thereof, for example, is prepared. Then, the insulating resin film is laminated on the upper surface of the support 51 and cured while applying heat and pressure on the insulating resin film, to form the insulating layer 12. Alternatively, instead of laminating the insulating resin film, a liquid or paste of the insulating resin may be coated on the upper surface of the support 51 and thereafter cured to form the insulating layer 12. The material used for the insulating layer 12 and the thickness of the insulating layer 12 are as described above.

Next, in the process (or step) illustrated in FIG. 2C, through holes 12z that penetrate the insulating layer 12 and expose the upper surface of the support 51 are formed in the insulating layer 12. The through holes 12z can be formed by a laser beam machining using a CO₂ laser or the like, for example. A cavity for providing an electronic component is formed by the upper surface of the support 51 and an inner surface defining the through hole 12z.

Next, in the process (or step) illustrated in FIG. 2D, the electronic component 60 including the electrodes 61 and 62 is prepared. Then, the electronic component 60 is disposed on the upper surface of the support 51 exposed inside the through hole 12z, with the electrode 61 facing the support 51. The electronic component 60 may be temporarily fixed to the upper surface of the support 51 using an adhesive.

Next, in the process (or step) illustrated in FIG. 2E, the embedding resin 13, which fills the through holes 12z to cover the electronic components 60 and extends upward from inside the through holes 12z to cover the upper surface of the insulating layer 12, is formed. Specifically, a semi-cured epoxy-based resin film or the like is laminated so as to cover the electronic components 60, and is cured to form the embedding resin 13, for example. Alternatively, instead of laminating the epoxy-based resin film or the like, a liquid or paste of the epoxy-based resin or the like may be coated on the electronic components 60 and the upper surface of the insulating layer 12, and thereafter cured to form the embedding resin 13. The material used for the embedding resin 13 and the thickness of the embedding resin 13 are as described above.

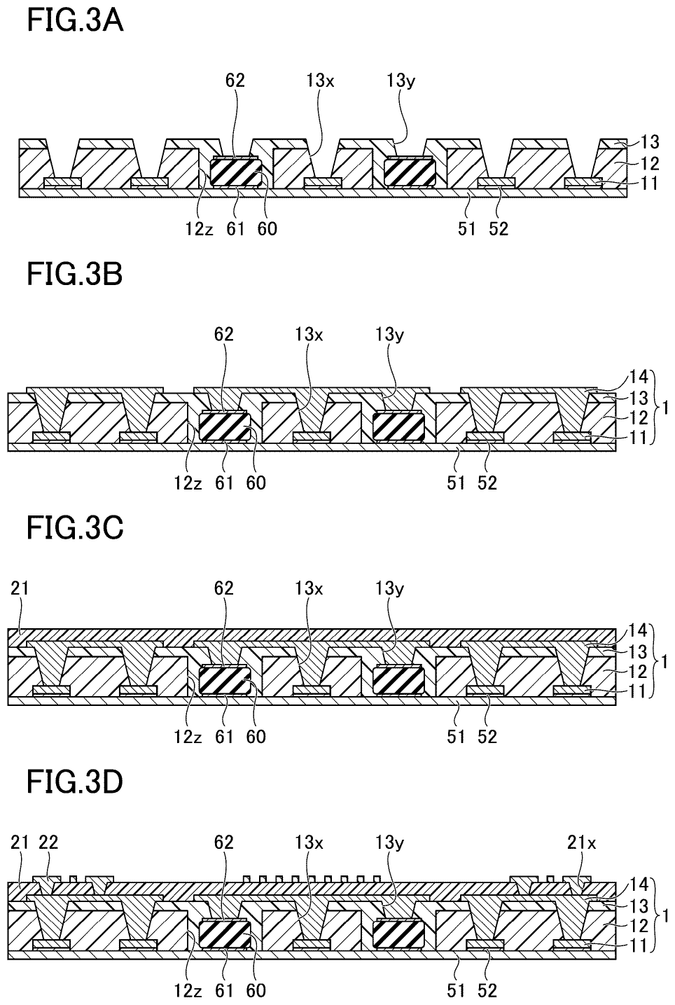

Next, in the process (or step) illustrated in FIG. 3A, the via holes 13x are formed in the insulating layer 12 and the embedding resin 13, so as to penetrate the insulating layer 12 and the embedding resin 13 and expose the upper surface of the interconnect layer 11. In addition, the via holes 13y are formed in the embedding resin 13, so as to penetrate the embedding resin 13 and expose the upper surface of the electrode 62 of the electronic components 60. The via hole 13x may have an inverted truncated cone shape such that the diameter of the via hole 13x that opens toward the upper surface of the embedding resin 13 is larger than the diameter of the bottom surface of the via hole 13x formed by the upper surface of the interconnect layer 11. The via hole 13y may have an inverted truncated cone shape such that the diameter of the via hole 13y that opens toward the upper surface of the embedding resin 13 is larger than the diameter of the bottom surface of the via hole 13y formed by the upper surface of the electrode 62. The via holes 13x and the via holes 13y can be formed by a laser beam machining using a CO₂ laser or the like, for example. After the via holes 13x and the via holes 13y are formed, a desmear process is preferably performed to remove resin residue adhered to the upper surface of the interconnect layer 11 exposed at the bottom of each via hole 13x and resin residue adhered to the upper surface of the electrode 62 exposed at the bottom of each via hole 13y, respectively.

Next, in the process (or step) illustrated in FIG. 3B, the interconnect layer 14 is formed. The interconnect layer 14 includes the via interconnects formed inside the via holes 13x and the via holes 13y, and the interconnect pattern formed on the upper surface of the embedding resin 13. The interconnect pattern includes portions electrically connected to the interconnect layer 11 through the via interconnects filling the via holes 13x. In addition, the interconnect pattern includes portions electrically connected to the electrodes 62 of the electronic components 60 through the via interconnects filling the via holes 13y.

The interconnect layer 14 can be formed using various interconnect forming methods, such as a semi-additive method, a subtractive method, or the like. In a case where the interconnect layer 14 is formed by the semi-additive method, a seed layer is formed on the upper surface of the embedding resin 13, the inner side surface defining the via holes 13x, the inner side surface defining the via holes 13y, the upper surface of the interconnect layer 11 exposed inside the via holes 13x, and the upper surface of the electrodes 62 exposed inside the via holes 13y, by electroless plating of copper (Cu), for example. Next, a plating resist pattern having an opening corresponding to a shape of the interconnect pattern of the interconnect layer 14 is formed on the seed layer, and an electrolytic plating layer is thereafter deposited on the seed layer exposed inside the opening of the plating resist pattern by electrolytic plating of copper (Cu) or the like using power supplied from the seed layer. Next, the plating resist pattern is removed, and an etching is thereafter performed using the electrolytic plating layer as a mask to remove the seed layer exposed from the electrolytic plating layer. Thus, the interconnect layer 14 having the via interconnects and the interconnect pattern can be obtained. The first interconnect structure 1 is completed by the processes (or steps) described above.

Next, in the process (or step) illustrated in FIG. 3C, an uncured insulating resin film, which covers the upper surface and the side surface of the interconnect pattern of the interconnect layer 14, is laminated on the embedding resin 13, for example. Then, the insulating resin film is cured while applying heat and pressure on the insulating resin film, against the embedding resin 13, to form the insulating layer 21. In this case, in order to reduce a skin effect, it is preferable to select an insulating resin film having a low roughness, such that a surface roughness Ra of the upper surface of the insulating resin film is 30 nm or less. The insulating resin film preferably has a low surface roughness Ra of 20 nm or less, and more preferably has a low surface roughness Ra of 10 nm or less. Instead of laminating the insulating resin film on the embedding resin 13, a liquid or paste the insulating resin may be coated on the embedding resin 13, and thereafter cured to form the insulating layer 21. In this case, in a case where the roughness of the upper surface of the insulating layer 21 is high, the upper surface of the insulating layer 21 is preferably smoothened by chemical mechanical polishing (CMP) or the like to set the roughness of the upper surface of the insulating layer 21 as described above, in order to reduce the skin effect. The material used for the insulating layer 21 and the thickness of the insulating layer 21 are as described above.

Next, in the process (or step) illustrated in FIG. 3D, the via holes 21x, which penetrate the insulating layer 21 and expose the upper surface of the interconnect layer 14, are formed, and the interconnect layer 22 is formed thereafter. The via holes 21x can be formed by a laser beam machining using a CO₂ laser or the like, for example. The interconnect layer 22 can be formed by a semi-additive method, for example, similar to the interconnect layer 14.

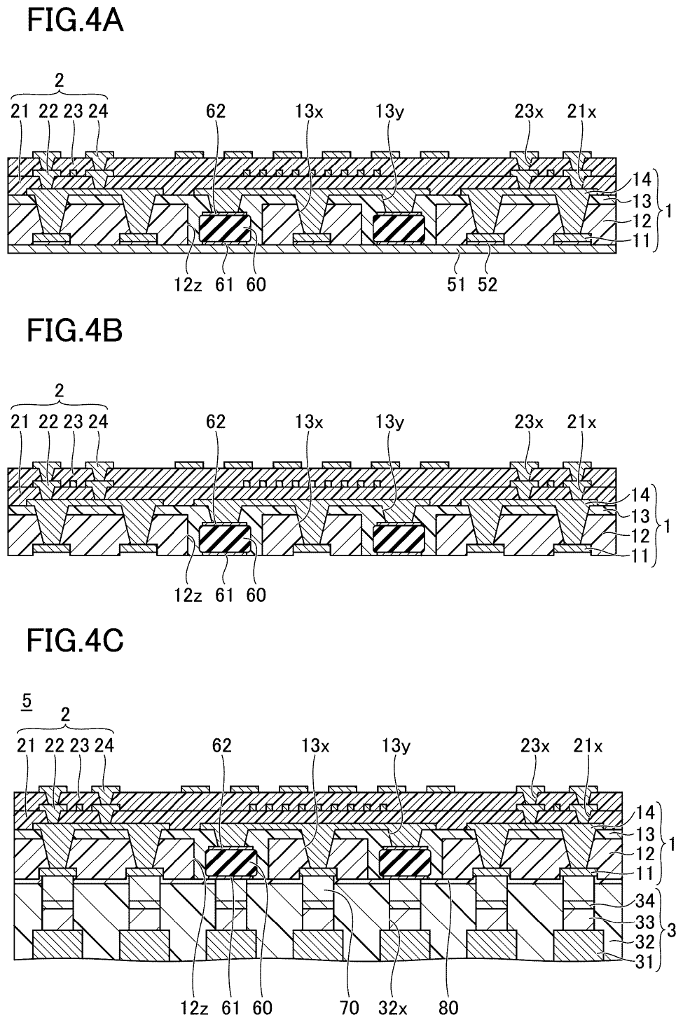

Next, in the process (or step) illustrated in FIG. 4A, the processes similar to those illustrated in FIG. 3C and FIG. 3D are repeated, to successively form the insulating layer 23 and the interconnect layer 24. Thus, the second interconnect structure 2 is completed.

Next, in the process (or step) illustrated in FIG. 4B, the support 51 and the sacrificial layer 52 illustrated in FIG. 4A are removed. In a case where the support 51 is formed of copper (Cu) and the sacrificial layer 52 is formed of nickel (Ni), for example, the support 51 is first removed by an etchant which can etch copper (Cu) but not nickel (Ni). Next, the sacrificial layer 52 is removed by an etchant which can etch nickel (Ni) but not copper (Cu). In this state, if the interconnect layer 11 is formed of copper (Cu), the interconnect layer 11 will not be removed even when the sacrificial layer 52 is removed. The lower surface of the interconnect layer 11 is exposed at a position recessed more toward the interconnect layer 14 than the lower surface of the insulating layer 12 is toward the interconnect layer 14. In addition, the lower surface of the electrode 62 of the electronic component 60 is exposed at a plane approximately coinciding with the lower surface of the insulating layer 12.

Next, in the process (or step) illustrated in FIG. 4C, a third interconnect structure 3 is prepared, and the third interconnect structure 3 and the first interconnect structure 1 are electrically connected. In this example, the third interconnect structure 3 including the interconnect layer 31, the insulating layer 32, and the metal layers 33 and 34 is prepared. The third interconnect structure 3 can be manufactured by a known build-up method, for example. After the third interconnect structure 3 is prepared, the metal layer 34 of the third interconnect structure 3 and the interconnect layer 11 of the first interconnect structure 1 are electrically connected via the bonding member 70, such as solder or the like. The underfill resin 80 is provided between the upper surface of the insulating layer 32 of the third interconnect structure 3 and the lower surfaces of the insulating layer 12 and the embedding resin 13 of the first interconnect structure 1, as required. Accordingly, the wiring board 5 is completed.

### Modifications of First Embodiment

In modifications of the first embodiment, examples of the wiring board having a configuration different from that of the first embodiment is illustrated. In the modifications of the first embodiment, a description of the constituent elements or components that are the same as those of the embodiment described above may be omitted.

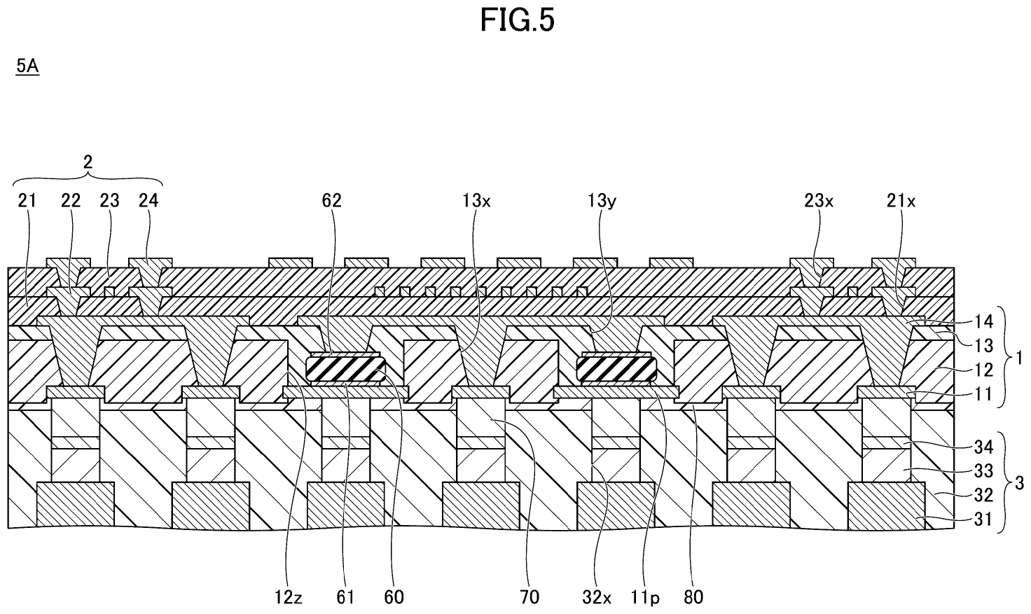

FIG. 5 is a cross sectional view illustrating the wiring board according to a first modification of the first embodiment. A wiring board 5A illustrated in FIG. 5 differs from the wiring board 5 in that the interconnect layer 11 includes an electronic component mounting pad 11p.

In the wiring board 5A, at least a portion of an upper surface of the electronic component mounting pad 11p is exposed inside the through hole 12z, a cavity is formed by the upper surface of the electronic component mounting pad 11p exposed inside the through hole 12z and the inner side surface defining the through hole 12z. The electronic component 60 is disposed inside the cavity. That is, the electronic component 60 is disposed on the upper surface of the electronic component mounting pad 11p exposed inside the through hole 12z. The electrode 61 of the electronic component 60 is electrically and mechanically connected to the electronic component mounting pad 11p via a conductive material, such as solder or the like, for example. The electronic component mounting pad 11p forms a portion of an electrical path connecting the electronic component 60 and the interconnect layer 31.

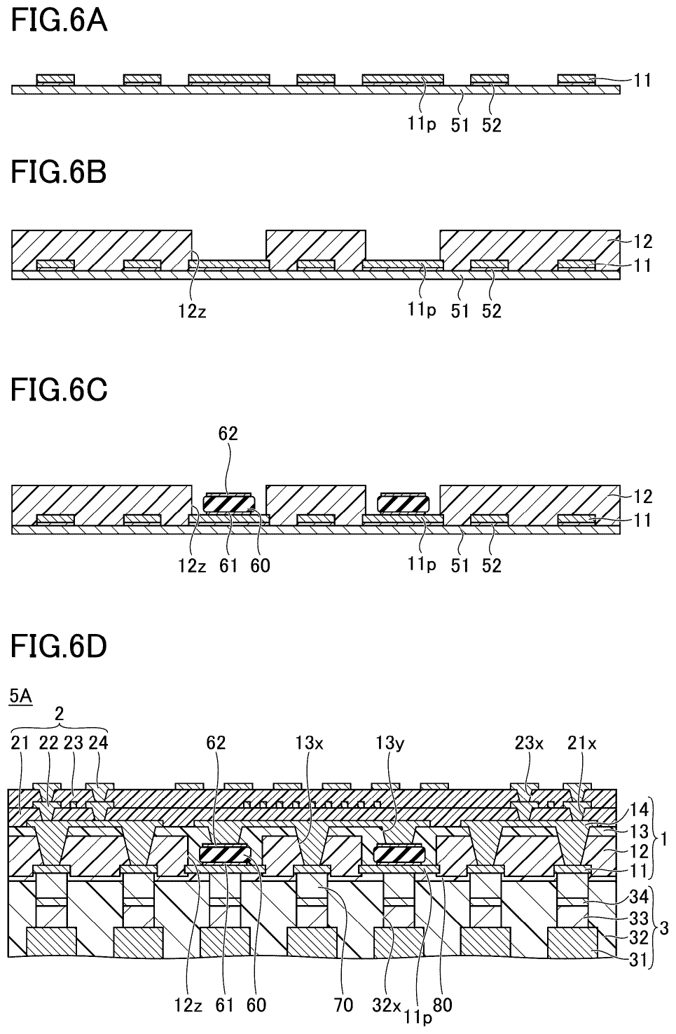

FIG. 6A through FIG. 6D are diagrams illustrating manufacturing processes of the wiring board according to the first modification of the first embodiment. The process (or step) illustrated in FIG. 6A is the same as the process (or step) illustrated in FIG. 2A, except that the interconnect layer 11 including the electronic component mounting pad 11p is formed on the support 51. Next, after forming the insulating layer in a manner similar to FIG. 2B, in the process (or step) illustrated in FIG. 6B, the through hole 12z is formed to penetrate the insulating layer 12 and to expose at least a portion of the upper surface of the electronic component mounting pad 11p. The cavity for mounting electronic component is formed by the upper surface of the electronic component mounting pad 11p and the inner surface defining the through hole 12z.

Next, in the process (or step) illustrated in FIG. 6C, the electronic component 60 including electrodes 61 and 62 is prepared. Then, the electronic component 60 is disposed on the upper surface of the electronic component mounting pad 11p exposed inside the through hole 12z with the electrode 61 facing the electronic component mounting pad 11p. The electrode 61 of the electronic component 60 is electrically and mechanically connected to the electronic component mounting pad 11p via a conductive material, such as solder or the like, for example. Next, in the process (or step) illustrated in FIG. 6D, processes similar to those illustrated in FIG. 2D through FIG. 4C are performed, and as a result, the wiring board 5A is completed.

Accordingly, the electronic component mounting pad 11p may be provided, and the electronic component 60 may be disposed on the upper surface of the electronic component mounting pad 11p. In such a configuration, the bonding member 70 does not need to be directly connected to the electrode 61 of the electronic component 60, and can be connected to the lower surface of the electronic component mounting pad 11p. Thus, a good connection is obtained between the electronic component mounting pad 11p and the bonding member 70. That is, a good connection is obtained between the electronic component 60 and the bonding member 70.

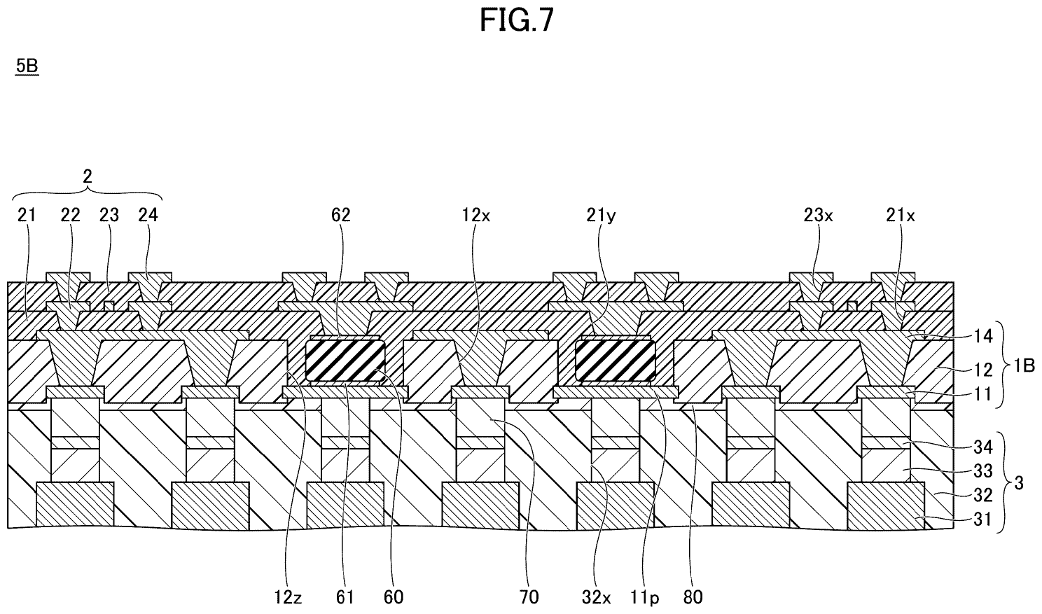

FIG. 7 is a cross sectional view illustrating the wiring board according to a second modification of the first embodiment. A wiring board 5B illustrated in FIG. 7 differs from the wiring board 5 in that the first interconnect structure 1 is replaced with a first interconnect structure 1B. The first interconnect structure 1B does not include the embedding resin 13. The wiring board 5B may or may not have the electronic component mounting pad 11p.

In the wiring board 5B, the embedding resin is formed integrally with the insulating layer 21 in contact with the insulating layer 12. In other words, the insulating layer 21 also serves as the embedding resin, and covers the upper surface of the insulating layer 12 and extends inside the through hole 12z to cover the electronic component 60. The insulating layer 21, which also serves as the embedding resin, extends from inside the through hole 12z to cover the upper surface of the insulating layer 12, and fills in between the insulating layer 12 as the first insulating layer and the insulating layer 23 as the second insulating layer. The electrode 62 of the electronic component 60 is directly connected to the interconnect layer 22. The upper side of the electronic component 60 may or may not protrude upward from the upper surface of the insulating layer 12.

In the method for manufacturing the wiring board 5B, the process (or step) illustrated in FIG. 2E is not performed. In the process (or step) illustrated in FIG. 3C, the insulating layer 21 is formed to fill the through hole 12z to cover the electronic component 60, and to extend upward from inside the through hole 12z to cover the upper surface of the insulating layer 12 and the upper surface of the interconnect layer 14. The other processes (or steps) may be the same as those of the method for manufacturing the wiring board 5.

Accordingly, the second insulating layer forming the second interconnect structure 2 may also serve as the embedding resin. In this case, the distance from the interconnect layer 24 to the electronic component 60 in the thickness direction can be made shorter than that in the case of the wiring board 5. Thus, when the semiconductor chip or the like is mounted on the second interconnect structure 2, the electrical path between the electronic component 60 and the semiconductor chip or the like can further be reduced, thereby further reducing the resistance loss. Further, because the process (or step) illustrated in FIG. 2E can be omitted, a manufacturing cost of the wiring board 5B can be reduced.

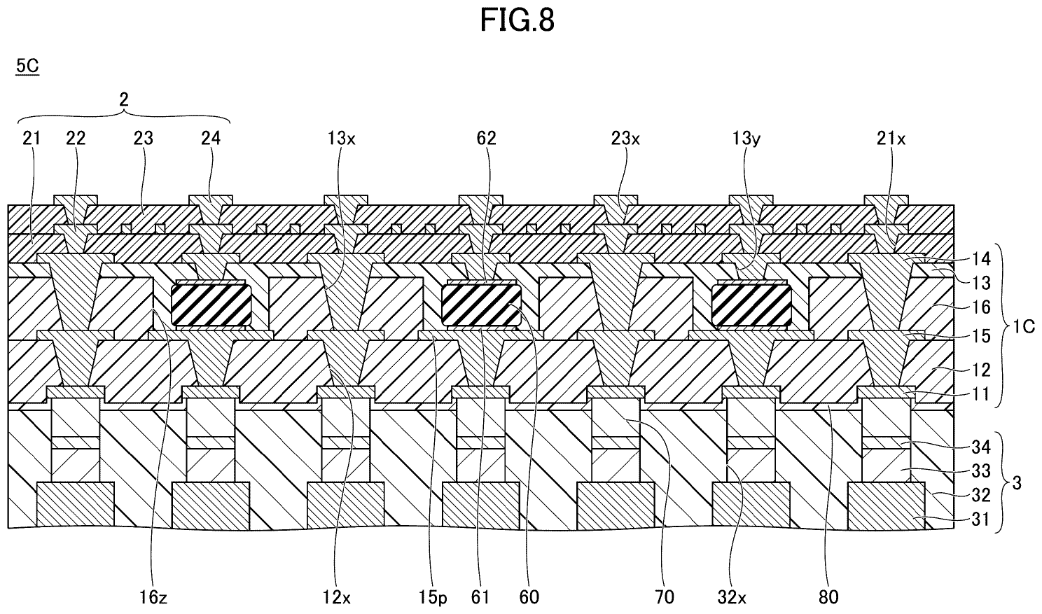

FIG. 8 is a cross sectional view illustrating the wiring board according to a third modification of the first embodiment. A wiring board 5C illustrated in FIG. 8 differs from the wiring board 5 in that the first interconnect structure 1 is replaced with a first interconnect structure 1C.

The first interconnect structure 1C differs from the first interconnect structure 1 in that the first interconnect structure 1C includes an interconnect layer 15 and an insulating layer 16. In the wiring board 5C, the insulating layer 12 is provided as a first interlayer insulating layer, and the insulating layer 16 and the embedding resin 13 are provided as a second interlayer insulating layer. The insulating layer 16 has a through hole 16z that exposes at least a portion of an upper surface of an electronic component mounting pad 15p, and the electronic component 60 is disposed on the upper surface of the electronic component mounting pad 15p exposed inside the through hole 16z. The embedding resin 13 fills the through hole 16z to cover the electronic component 60, and extends upward from inside the through hole 16z to cover an upper surface of the insulating layer 16, and fills in between the insulating layer 16 as the first insulating layer and the insulating layer 21 as the second insulating layer. The wiring board 5C may or may not have the electronic component mounting pad 15p.

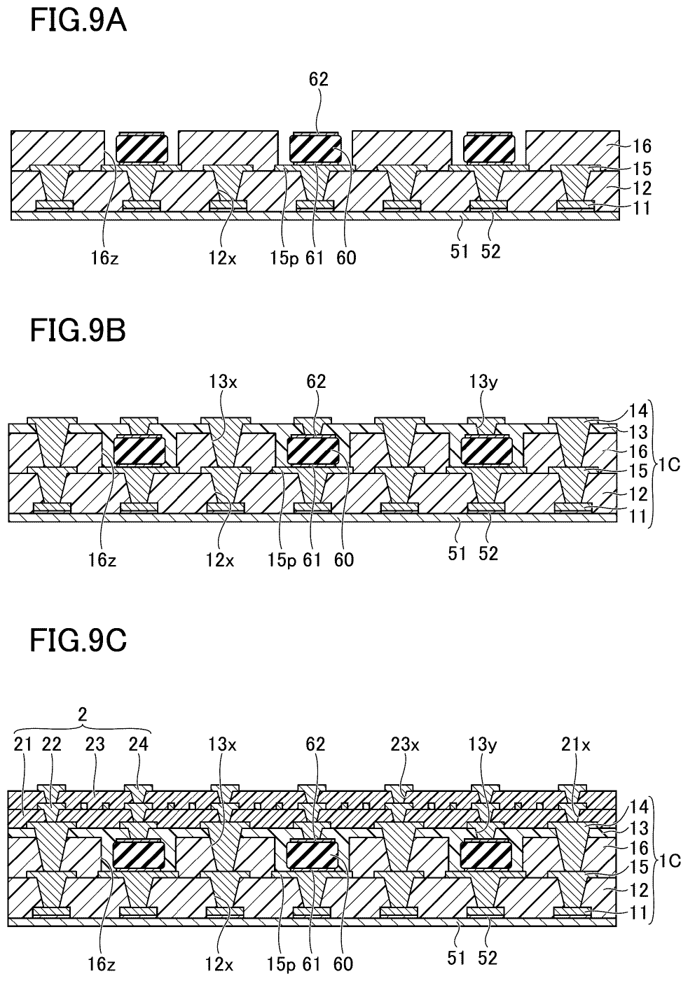

FIG. 9A through FIG. 9C are diagrams illustrating manufacturing processes of the wiring board according to the third modification of the first embodiment. In order to manufacture the wiring board 5C, first, in the process (or step) illustrated in FIG. 9A, the sacrificial layer 52, the interconnect layer 11, the insulating layer 12, the interconnect layer 15, and the insulating layer 16 are successively formed on the support 51 by a method similar to that of the first embodiment. Then, the through hole 16z is formed in the insulating layer 16, and the electronic component 60 is disposed inside the through hole 16z.

Next, in the process (or step) illustrated in FIG. 9B, the embedding resin 13 is formed by a method similar to that of the first embodiment, so as to fill the through hole 16z to cover the electronic component 60, and to extend upward from inside the through hole 16z to cover the upper surface of the insulating layer 16. Thereafter, the via holes 13x and 13y are formed, and further, the interconnect layer 14 is formed. Then, in the process (or step) illustrated in FIG. 9C, the second interconnect structure 2 is formed on the first interconnect structure 1 by a method similar to that of the first embodiment. Moreover, the first interconnect structure 1 and the third interconnect structure 3 are bonded by a method similar to that of the first embodiment, and as a result, the wiring board 5C is completed.

Accordingly, the first interconnect structure may include a plurality of insulating layers, and in this case, the electronic component 60 can be embedded in an arbitrary insulating layer among the plurality of insulating layers. The first interconnect structure 1C may include three or more insulating layers. In the case where the first interconnect structure 1C includes a plurality of insulating layers, the electronic component 60 is preferably disposed inside a through hole that penetrates the uppermost insulating layer from a viewpoint of shortening the electrical path to the semiconductor chip or the like provided on the second interconnect structure 2 and reducing the resistance loss.

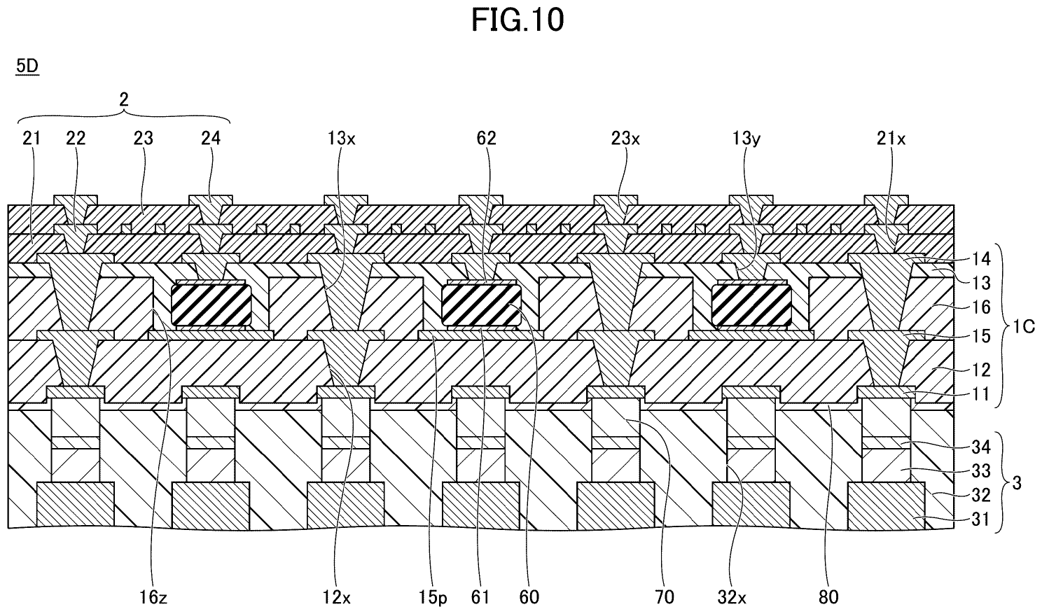

FIG. 10 is a cross sectional view illustrating the wiring board according to a fourth modification of the first embodiment. A wiring board 5D illustrated in FIG. 10 differs from the wiring board 5C in that the electronic component mounting pad 15p is not electrically connected to the interconnect layer 11. That is, in the wiring board 5D, the electronic component 60 is electrically connected only to the interconnect layer located above the interconnect layer 15. In this case, an electronic component that does not have the electrode 61 may be disposed on the electronic component mounting pad 15p. In this case, a lower surface of the electronic component and the upper surface of the electronic component mounting pad 15p may be fixed by an insulating adhesive.

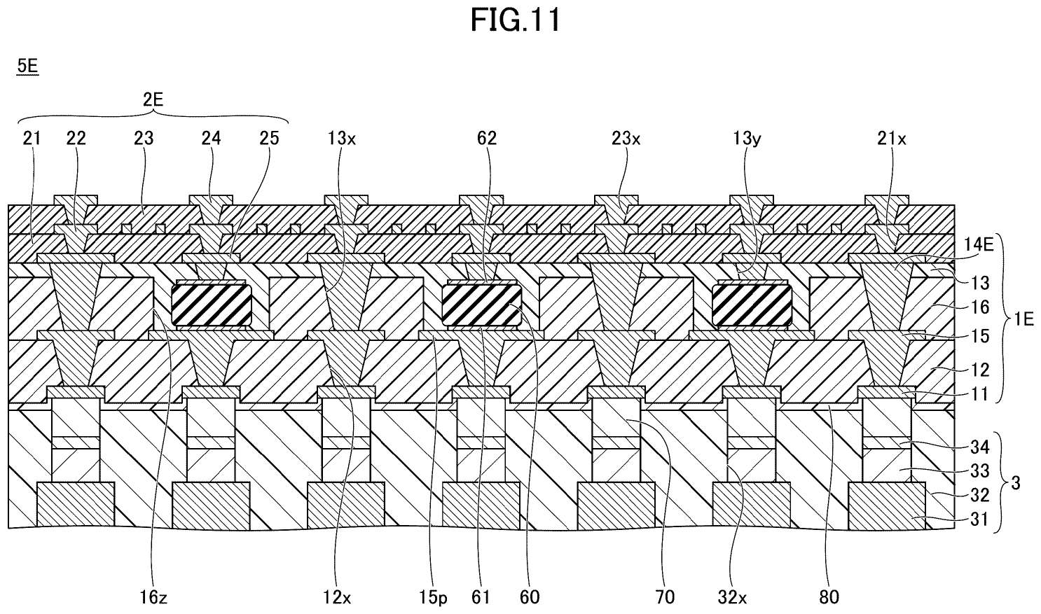

FIG. 11 is a cross sectional view illustrating the wiring board according to a fifth modification of the first embodiment. A wiring board 5E illustrated in FIG. 11 differs from the wiring board 5C in that the first interconnect structure 1C is replaced with a first interconnect structure 1E and the second interconnect structure 2 is replaced with a second interconnect structure 2E.

The first interconnect structure 1E differs from the first interconnect structure 1C in that the interconnect layer 14 is replaced with a via interconnect 14E. The second interconnect structure 2E differs from the second interconnect structure 2 in that an interconnect layer 25 is additionally provided. The via interconnect 14E is an example of the first interconnect layer. The interconnect layer 25 is an example of the second interconnect layer. The wiring board 5E may or may not have the electronic component mounting pad 15p.

The via interconnect 14E fills each of the via holes 13x and 13y. The via interconnect 14E does not have a portion extending on the embedding resin 13. An upper surface of the via interconnect 14E is exposed from the upper surface of the embedding resin 13 in contact with the insulating layer 21. The upper surface of the via interconnect 14E coincides with the upper surface of the embedding resin 13 in contact with the insulating layer 21, for example. The upper surface of the via interconnect 14E and the upper surface of the embedding resin 13 are polished surfaces. For this reason, the upper surface of the via interconnect 14E and the upper surface of the embedding resin 13 are smooth surfaces (surfaces with a low roughness) with few irregularities. The upper surface of the via interconnect 14E and the upper surface of the embedding resin 13 may have a surface roughness Ra in a range of approximately 15 nm to approximately 40 nm.

The interconnect layer 25 is formed on the upper surface of the embedding resin 13 and the upper surface of the via interconnect 14E. A portion of the lower surface of the interconnect layer 25 is in contact with the upper surface of the via interconnect 14E, and the two are electrically connected. That is, the via interconnect 14E is directly connected to the interconnect layer 25 which is the lowermost second interconnect layer. The interconnect layer 25 includes a portion electrically connected to the interconnect layer 15 through the via interconnect 14E. The interconnect layer 25 includes a portion electrically connected to the electrode 62 of the electronic component 60 through the via interconnect 14E. The interconnect layer 25 is electrically connected to the via interconnect of the interconnect layer 22. A material used for the interconnect layer 25 may be the same as the material used for the interconnect layer 22, for example. A thickness of the interconnect layer 25 may be the same as the thickness of the interconnect pattern of the interconnect layer 22, for example. A line/space of the interconnect layer 25 may be the same as the line/space of the interconnect pattern of the interconnect layer 22, for example.

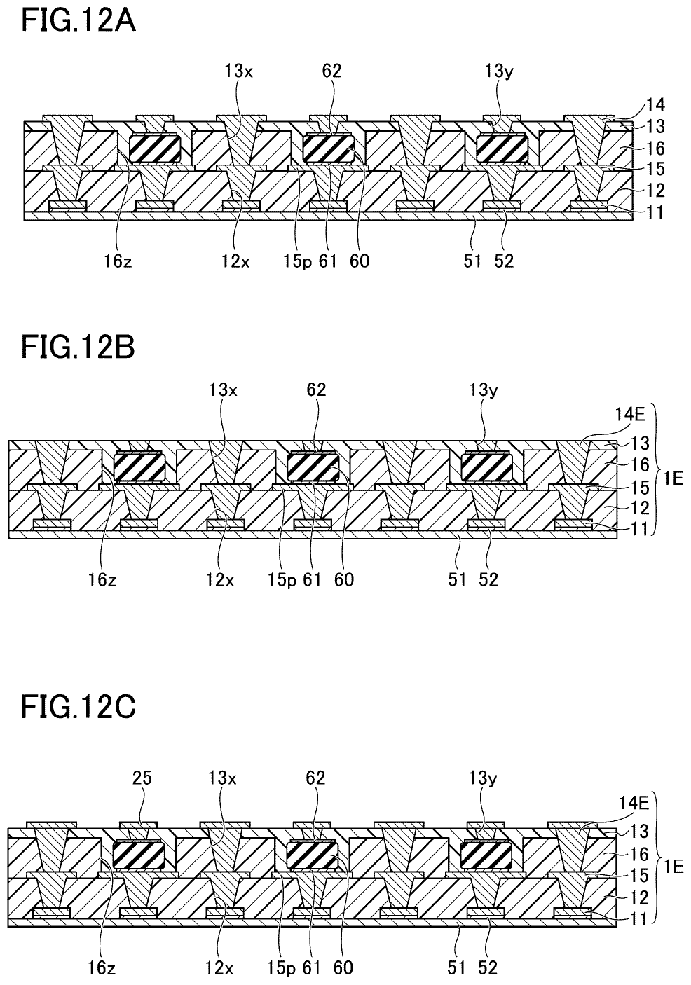

FIG. 12A through FIG. 12C are diagrams illustrating the manufacturing processes of the wiring board according to the fifth modification of the first embodiment. In order to manufacture the wiring board 5E, first, in the process (or step) illustrated in FIG. 12A, a process similar to that illustrated in FIG. 9B is performed. Next, in the process (or step) illustrated in FIG. 12B, the upper surface of the interconnect layer 14 and the upper surface of the embedding resin 13 are polished to form the via interconnect 14E. Thus, the first interconnect structure 1E is completed. For example, a chemical mechanical polishing (CMP) can be used for the polishing. After the polishing, the upper surface of the via interconnect 14E and the upper surface of the embedding resin 13 can be made to coincide with each other, for example. The polished upper surface of the via interconnect 14E and the polished upper surface of the embedding resin 13 may have a surface roughness Ra in a range of approximately 15 nm to approximately 40 nm. The roughness of the lower surface of the embedding resin 13 is in a range of approximately 180 nm to approximately 280 nm in terms of the surface roughness Ra, for example.

Next, in the process (or step) illustrated in FIG. 12C, the interconnect layer 25 is formed on the upper surface of the via interconnect 14E and the upper surface of the embedding resin 13. A portion of the lower surface of the interconnect layer 25 is in contact with the upper surface of the via interconnect 14E, and the two are electrically connected. The interconnect layer 25 may be formed by a semi-additive method, for example, similar to the interconnect layer 14.

In the process (or step) illustrated in FIG. 12A, the upper surface of the embedding resin 13 covering the electronic component 60 may be recessed. In this case, the upper surface of the interconnect layer 14 located on the electronic component 60 is located at a position lower than the upper surface of the interconnect layer 14 not located on the electronic component 60. For this reason, the insulating layer 21 formed thereafter also includes a recess (or unevenness), and it is difficult to form the fine interconnect layer 22. For this reason, the process (or step) illustrated in FIG. 12B is provided to smoothen the upper surface of the via interconnect 14E and the upper surface of the embedding resin 13, and to reduce the surface roughnesses thereof. Then, the process (or step) illustrated in FIG. 12C is further provided to form the interconnect layer 25 on the upper surface of the via interconnect 14E and the upper surface of the embedding resin 13. This enables the formation of the fine interconnect layer 25. In addition, because a variation in a height of the upper surface of the interconnect layer 24 serving as the external connection terminal is reduced, a connection reliability can be improved when connecting the interconnect layer 24 to the electrode of the semiconductor chip.

The wiring boards 5, 5A, 5B, and 5D may also have a configuration including the via interconnect 14E. For example, when the wiring board 5 includes the via interconnect 14E, the upper surface of the via interconnect 14E is exposed from the upper surface of the insulating layer 12 in contact with the insulating layer 21. The upper surface of the via interconnect 14E coincides with the upper surface of the insulating layer 12 in contact with the insulating layer 21, for example. In addition, the via interconnect 14E is directly connected to the interconnect layer 25 which is the lowermost second interconnect layer. Further, the method for manufacturing the wiring board 5B includes the process (or step) of forming the via interconnect 14E having the upper surface thereof coinciding with the upper surface of the insulating layer 12, on the insulating layer 12 in contact with the insulating layer 21.

### Application Example of First Embodiment

In an application example of the first embodiment, an example of a semiconductor device in which the semiconductor chip is mounted on the wiring board will be described. In the application example of the first embodiment, a description of the constituent elements or components that are the same as those of the embodiment described above may be omitted.

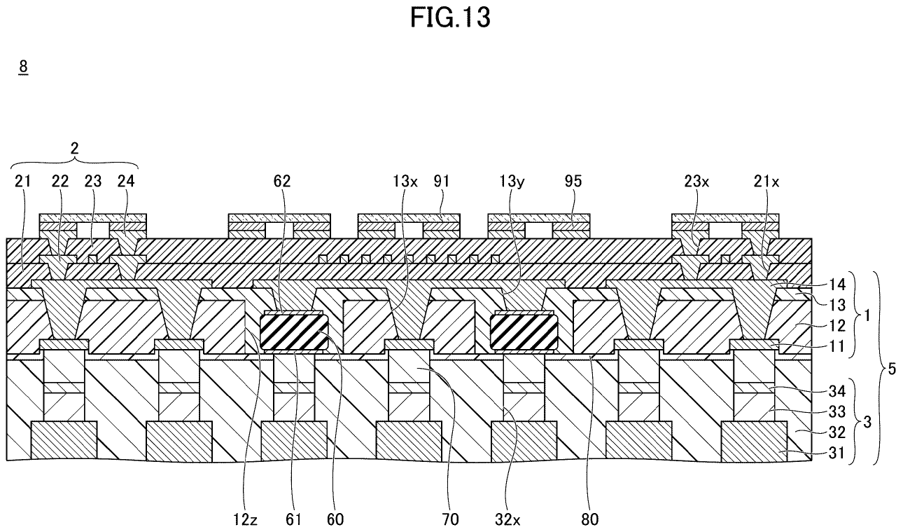

FIG. 13 is a cross sectional view illustrating the semiconductor device according to the application example of the first embodiment. As illustrated in FIG. 13, a semiconductor device 8 includes the wiring board 5 illustrated in FIG. 1, a semiconductor chip 91, and bumps 95. The semiconductor chip 91 is provided on the second interconnect structure 2 of the wiring board 5.

The semiconductor chip 91 is obtained by forming a semiconductor integrated circuit (not illustrated) or the like on a thinned semiconductor substrate (not illustrated) formed of silicon (Si) or the like, for example. Electrodes electrically connected to the semiconductor integrated circuit (not illustrated) are formed on the semiconductor substrate (not illustrated). The electrodes are connection terminals connected to the wiring board 5, and are copper (Cu) posts, for example. The semiconductor chip 91 may be a processor, such as a central processing unit (CPU), a graphics processing unit (GPU), or the like, for example. The semiconductor chip 91 may be a memory, such as a high bandwidth memory (HBM) or the like, for example.

The electrodes of the semiconductor chip 91 are electrically connected to the interconnect layer 24 of the wiring board 5 via the bumps 95. The bumps 95 are solder bumps, for example. Examples of a material used for the solder include an alloy including Pb, an alloy of Sn and Cu, an alloy of Sn and Ag, an alloy of Sn, Ag, and Cu, or the like, for example. An underfill resin may fill in between the semiconductor chip 91 and the upper surface of the wiring board 5.

Accordingly, the semiconductor device 8 can be obtained by providing the semiconductor chip 91 on the wiring board 5 according to the first embodiment. The wiring board 5 can be suitably used as an interposer substrate for high-speed data communication between a processor and a memory, for example. Further, by using the wiring board 5, the electrical path between the electronic component 60 and the semiconductor chip 91 is shortened, and the resistance loss can be reduced. Accordingly, it is possible to improve the power supply efficiency and to stabilize the power supply.

Although the modifications of the embodiment are numbered with, for example, “first,” “second,” or the like, the ordinal numbers do not imply priorities of the modifications. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

According to the disclosed technique, it is possible to reduce a resistance loss in a wiring board having an electronic component embedded therein.

Various aspects of the subject-matter described herein may be set out non-exhaustively in the following numbered clauses:
1. A method for manufacturing a wiring board having a first interconnect structure that includes a first interconnect layer and a first insulating layer, a second interconnect structure that includes a second interconnect layer and a second insulating layer and is laminated on one side of the first interconnect structure, and a third interconnect structure that includes a third interconnect layer and a third insulating layer and is laminated on the other side of the first interconnect structure, the method for manufacturing the wiring board comprising:
   forming the first insulating layer;
   forming the first interconnect layer;
   forming a through hole in the first insulating layer, the through hole penetrating the first insulating layer;
   disposing an electronic component inside the through hole;
   forming the second insulating layer that fills the through hole to cover the electronic component and extends upward from inside the through hole to cover the upper surface of the first insulating layer; and
   forming the second interconnect layer on the second insulating layer, the second interconnect layer being electrically connected to the first interconnect layer and the electronic component.
2. The method for manufacturing the wiring board according to clause 1, wherein the forming the first interconnect layer includes forming a first via interconnect on the first insulating layer in contact with the second insulating layer, the first via interconnect having an upper surface coinciding with the upper surface of the first insulating layer.

What is claimed is:

1. A wiring board comprising:
a first interconnect structure including a first interconnect layer and a first insulating layer;
a second interconnect structure, including a second interconnect layer and a second insulating layer, and laminated on one side of the first interconnect structure; and
a third interconnect structure, including a third interconnect layer and a third insulating layer, and laminated on the other side of the first interconnect structure, wherein
the second interconnect layer has an interconnect density higher than interconnect densities of the first interconnect layer and the third interconnect layer,
the first insulating layer has a through hole penetrating the first insulating layer,
an electronic component electrically connected to the second interconnect layer is disposed inside the through hole,
an embedding resin covering the electronic component is provided inside the through hole, and
the embedding resin extends from inside the through hole to cover the first insulating layer, and fills in between the first insulating layer and the second insulating layer.

2. The wiring board as claimed in claim 1, wherein:
the first interconnect layer includes an electronic component mounting pad,
at least a portion of an upper surface of the electronic component mounting pad is exposed inside the through hole, and
the electronic component is disposed on the upper surface of the electronic component mounting pad exposed inside the through hole.

3. The wiring board as claimed in claim 2, wherein the electronic component mounting pad forms a portion of an electrical path connecting the electronic component and the third interconnect layer.

4. The wiring board as claimed in claim 1, wherein:
the embedding resin is formed integrally with the second insulating layer in contact with the first insulating layer, and
an electrode of the electronic component is directly connected to the second interconnect layer.

5. The wiring board as claimed in claim 4, wherein:
the first interconnect layer includes a first via interconnect,
an upper surface of the first via interconnect is exposed from an upper surface of the first insulating layer in contact with the second insulating layer,
the upper surface of the first via interconnect coincides with the upper surface of the first insulating layer in contact with the second insulating layer, and
the first via interconnect is directly connected to a lowermost layer of the second interconnect layer.

6. The wiring board as claimed in claim 1, wherein:
the first interconnect layer includes a first via interconnect,
an upper surface of the first via interconnect is exposed from an upper surface of the embedding resin in contact with the second insulating layer,
the upper surface of the first via interconnect coincides with the upper surface of the embedding resin in contact with the second insulating layer, and
the first via interconnect is directly connected to a lowermost layer of the second interconnect layer.

7. The wiring board as claimed in claim 1, wherein:
the first interconnect structure includes a plurality of the first insulating layers, and
the electronic component is disposed inside the through hole that penetrates an uppermost layer of the first insulating layer.

8. A semiconductor device comprising:
the wiring board according to claim 1; and
a semiconductor chip provided on the second interconnect structure of the wiring board.
